(19) United States
(12) Patent Application Publication
(10) Pub. No.: US 2010/0180961 A1
(43) Pub. Date: Jul. 22, 2010

(54) MICROFLUIDIC STRUCTURES WITH INTEGRATED DEVICES

(76) Inventors: Olivier Lobet, Mennecy (FR); Paulo Gaspar Jorge Marques, Fountainbleau (FR); Ronan Tanguy, Grez Sur Loing (FR)

Correspondence Address: CORNING INCORPORATED, SP-TI-3-1, CORNING, NY, 14831, US

(21) Appl. No.: 12/596,945

(22) PCT Filed: Dec. 21, 2007
(86) PCT No.: PCT/US07/26227

§ 371 Date: Mar. 25, 2010

(30) Foreign Application Priority Data
Dec. 29, 2006 (EP) 06301310.6

(51) Int. Cl. B81B 1/00; B81C 1/00

(52) U.S. Cl. 137/341; 29/428; 137/561 R

(57) ABSTRACT

A microfluidic device having a glass, glass-ceramic, or ceramic structure, said structure including one or more passages defined therein with at least one first passage accessible through at least one first port wherein the first passage contains at least one solid object disposed therein said solid object including a material having a coefficient of thermal expansion differeing from the glass, glass-ceramic, or ceramic of said structure, said solid object resting in said first passage substantially without compressive stress from an inside surface of said passage at room temperature.

### BACKGROUND

The present invention relates generally to microfluidic structures with integrated devices, and particularly to microfluidic structures formed of glass, glass-ceramic or ceramic material, having integrated solid structures comprised of materials having differing coefficients of thermal expansion relative to the glass, glass-ceramic or ceramic material.

Microfluidic devices as herein understood are generally devices containing fluidic passages or chambers having typically at least one and generally more dimensions in the sub-millimeter to millimeters range, up to a maximum dimension of labout 10 mm. Microfluidic devices can be useful to perform difficult, dangerous, or even otherwise impossible chemical reactions and processes in a safe, efficient, and environmentally-friendly way.

As shown in FIG. 1 (Prior Art), microfluidic devices 10 formed of structured consolidated frit 20 of glass, glass-ceramic or ceramic, with the structured frit defining recesses or passages 22 between two or more substrates 24, have been developed in previous work by the present inventors and/or their associates, as disclosed for example in U.S. Pat. No. 6,769,444, “Microfluidic Device and Manufacture Thereof” and related patents or patent publications. Methods disclosed therein include various steps including providing a first substrate, providing a second substrate, forming a first frit structure on a facing surface of said first substrate, forming a second frit structure on a facing surface of said second substrate, and consolidating said first substrate and said second substrate and said first and second frit structures together, with facing surfaces toward each other, so as to form one or more consolidated-flit-defined recesses or passages between said first and second substrates.

Also disclosed is additional “functionalization” of the subject microfluidic devices by the use of additional parts such as electrical conductors, electrodes, light conductors, and the like, that can be used as heater mechanisms, sensors, and the like. As therein disclosed, such parts are generally incorporated in the one-piece microstructure (the consolidated frit 20), optionally in contact with one of the substrates 24, and optionally opening out into a recess 22, as shown in FIG. 1 by integrated part 26. Further according to the disclosure, such parts may also be arranged on or in intermediate layers 28, such as thin Si, glass, or glass ceramic, by printing conducting layers or the like to form the part 30, then positioning the material of the thin intermediate layer 28 between a substrate 24 and a formed-frit structure (the precursor structure of a consolidated frit structure 20) during assembly of the device, as shown by integrated part 30. While the devices resulting and the methods of manufacture thus disclosed can be useful, it has become desirable to increase the ease of production and the reliability of microfluidic devices comprising glass, glass-ceramic or ceramic structures and including solid structures comprised of materials dissimilar to the frit material or its constituents.

### SUMMARY OF THE INVENTION

According to one embodiment of the present invention, a microfluidic device has a glass, glass-ceramic, or ceramic structure, and the structure includes one or more passages defined therein, with at least one first passage accessible through at least one first port. The first passage further contains at least one solid object disposed therein and the solid object includes a material having a coefficient of thermal expansion differing from the glass, glass-ceramic, or ceramic of said structure, and said solid object rests in said first passage substantially without compressive stress from an inside surface of said passage at room temperature.

According to another embodiment of the present invention, a method of making a microfluidic device comprising glass, glass-ceramic, or ceramic and having a solid structure incorporated therein having a thermal expansion coefficient differing from said glass, glass-ceramic, or ceramic, comprises providing a solid structure for incorporation into a microfluidic device, forming, in a glass, glass-ceramic, or ceramic material, an open-ceiling passage, positioning the solid structure in the passage, and enclosing the solid structure within the passage so as to form an enclosed passage within said device containing the solid structure.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention and, together with the description, serve to explain the principles and operations of the invention.

### BRIEF DESCRIPTION OF THE DRAWINGS

FIG. 1 is a cross-section of a prior art microfluidic device.

FIG. 2 is a plan view of a heater element that may optionally be used in the present invention.

FIG. 3 is a plan view of of open-ceiling passage comprised of frit walls formed on a substrate for use with the heater element of FIG. 2 according to an embodiment of the present invention.

FIG. 4 is a plan view of the heater element of FIG. 2 assembled together with the frit walls formed on a substrate of FIG. 3.

FIG. 5 is a partial cross-sectional elevational view of an arrangement of frit walls on a substrate such as they may appear prior to final consolidation in the embodiment of FIGS. 2-4 or in other embodiments of the present invention.

FIG. 6 is a partial cross-sectional elevational view of an arrangement of frit walls on a substrate such as they may appear after final consolidation in the embodiment of FIGS. 2-4 or in other embodiments of the present invention.

FIG. 7 is a partial cross-sectional elevational view of a device like that of FIG. 6 but with an additional layer of passages above the layer of passages of FIG. 6.

FIG. 8 is a partial cross-sectional elevation view of an alternative embodiment of the present invention.

FIG. 9 is a plan view of yet another embodiment of the present invention.

FIG. 10 is plan view of still another embodiment of the present invention.

FIGS. 11 and 12 are partial cross-sectional elevation view of yet another alternative embodiment of the present invention, FIG. 11 at room temperature and FIG. 12 at elevated temperature.

FIG. 13 is a partial cross-sectional elevation view of still another alternative embodiment of the present invention.

FIG. 14 is plan view of still another alternative embodiment of the present invention.

FIG. 15 is a partial plan view of yet another embodiment of the present invention.

FIG. 16 is a partial plan view of still another embodiment of the present invention.

FIG. 17 is a partial plan view of yet another embodiment of the present invention.

FIG. 18 is a partial plan view of still another embodiment of the present invention.

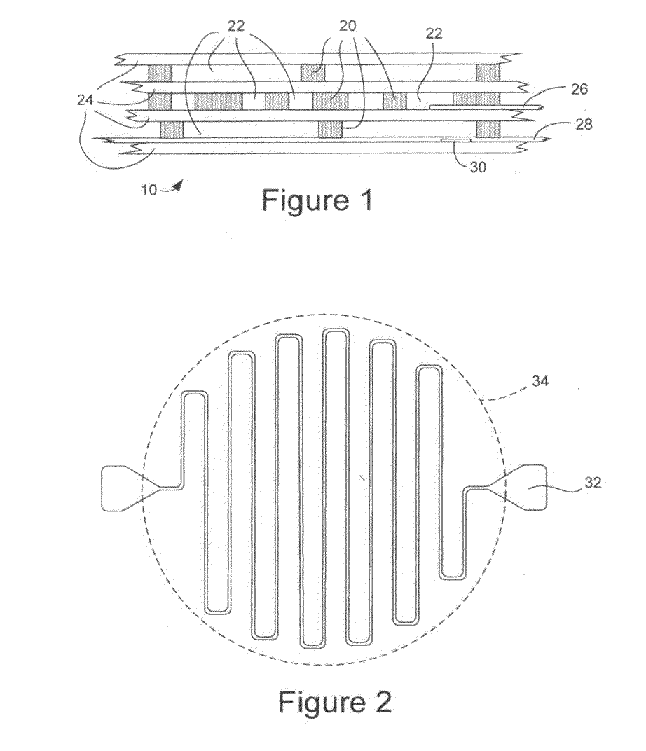

### DETAILED DESCRIPTION

Reference will now be made in detail to the present preferred embodiments of the invention, instances of which are illustrated in the accompanying drawings. Whenever possible, the same reference numerals will be used throughout the drawings to refer to the same or like parts.

The present invention provides methods for incorporating or integrating, into a microfluidic device formed at least in part of glass, glass-ceramic, or ceramic materials, objects comprising materials that are of dissimilar coefficient of thermal expansion relative to the glass, glass-ceramic, or ceramic materials. One alternative embodiment of such an object is shown in FIG. 2, which is a plan view of a metallic solid object in the form of a resistive heater element 32 to be incorporated in a microfluidic device, superimposed with a dashed outline 34 showing the extent of the associated microfluidic device.

The resistive heater element 32 may be formed of nickel-chromium alloy or other suitable material. The resistive heater element 32 has an extended tortuous shape so as to be able to uniformly heat the area shown by the dashed outline 34.

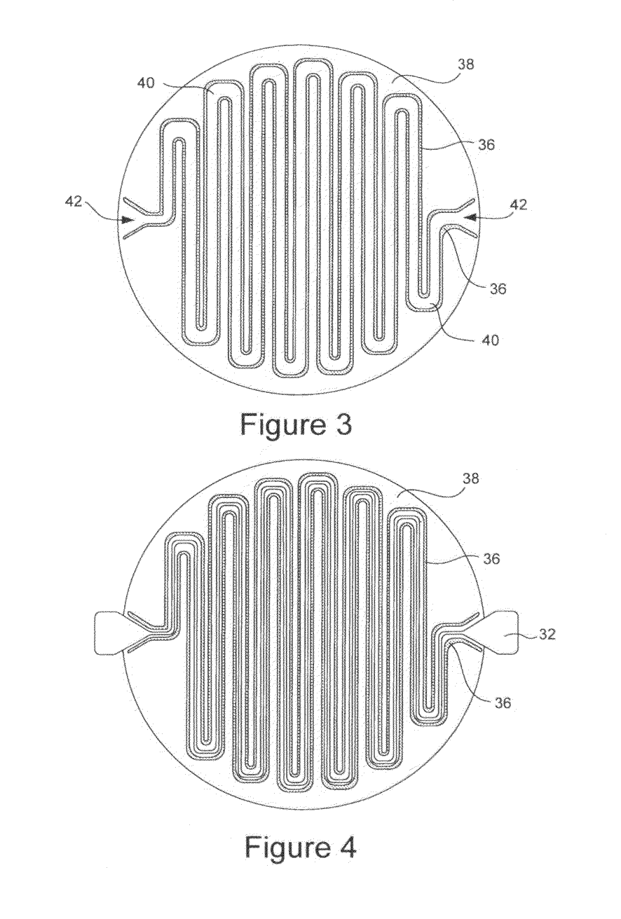

To incorporate the heater element 32 or any similar object according to one embodiment of the present invention, wall structures 36 comprising a frit material are formed on a substrate 38 as shown in plan view in FIG. 3, such as by molding onto the substrate with an organic or inorganic binder, or by other suitable forming process. The wall structures 36 define between them an open-ceiling passage in the form of a tortuous path 40 corresponding to the extended tortuous shape of the heater element 34. The tortuous path 40 is accessible by at least one, and in this embodiment, two access ports 42.

After the wall structures 36 are formed on the substrate 38, the heater element 32 is positioned within the open-ceiling passage or tortuous path 40 as shown in FIG. 4. The wall structures 36 may be partially consolidated as by de-binding or pre-sintering, or may remain in an as-molded state during the positioning of the heater element 32 if the binder and the molding process selected provide sufficient strength that the wall structures are not too easily disturbed by the positioning of the heater element 32.

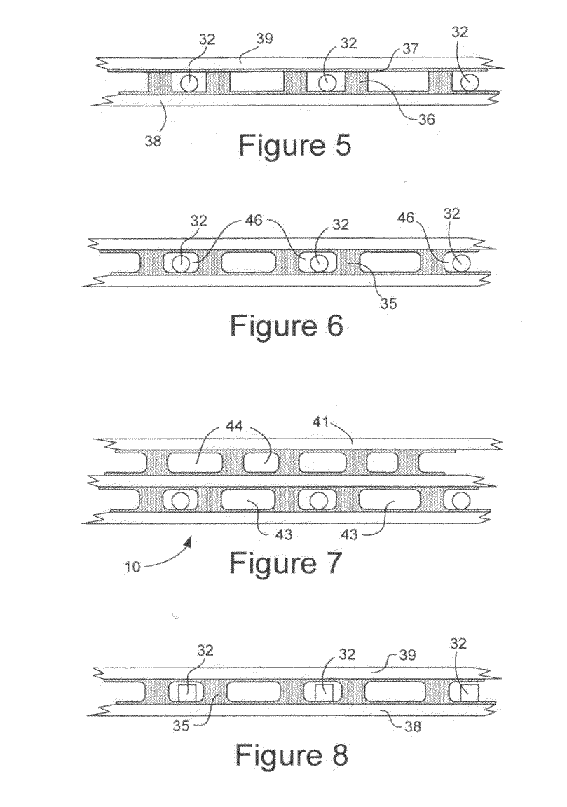

With reference to FIG. 5, which is an elevational partial cross-section of FIG. 4, an upper substrate 39 is then placed on the wall structures 36 previously formed on the substrate 38. This encloses the heater element 32. The upper substrate would typically include its own upper flit structure 37 formed thereon by molding or other suitable process. The upper frit structure 37 may include wall structures matching the wall structures 36 or may simply be a thin flat layer comprising frit, as in the embodiment shown in FIG. 5.

The frit structures 36 and 37 between the substrates 38 and 39 are then consolidated, as by thermal sintering, for example, resulting in the consolidated wall structure 35 shown in FIG. 6. The heater element 32 is thus enclosed within the passage 46 formed from the open-ceiling passage or path 40. Thus a closed tortuous passage 46 is formed between the first substrate 38 and the upper substrate 39, with the tortuous passage 46 containing a tortuous solid structure in the form of the heater element 32. At the same consolidation step or in a subsequent consolidation step, additional passages such as fluidic passages 44 may be formed between upper substrate 39 and a third substrate 41 in similar fashion, resulting in the device 10 of FIG. 7. Alternatively or in addition, the shape of the element 32 and the tortuous passage 46 may be chosen such that some or all of the spaces 43 remaining between substrate 38 and the upper substrate 39 that are not part of the tortuous passage 46 may be used as fluidic passages. As will be seen below, in other embodiments of the invention, a solid structure may be added to a fluidic passage.

As will be understood from the foregoing, heater element 32 or other elements to be incorporated by the various embodiments of the process of the present invention should generally comprise temperature resistant materials, since the forming process of the passage 46 in which the element 32 resides involves consolidation of fit typically through thermal sintering. Resistive heater elements and metallic thermocouples are useful objects to incorporate and ideal candidates as they can be formed of temperature resistant metals. The objects to be incorporated need not have a tortuous shape, as a single thermocouple need not, for example. However, it may be desirable to provide a network of multiple thermocouple locations within what would likely be a rather tortuous path so as to distribute the sensing capability in a desirable pattern throughout the device.

For forming a resistive heater element such as resistive heater element 32 of FIG. 2, it is desirable for manufacturing ease to use an automated process, such as an automatic wire forming machine, or to form the element 32 out of a sheet or foil of the desired metal, such as by etching or by stamping. Etching or stamping typically results in a more rectangular profile for the device wires, as represented by element 32 shown in FIG. 8.

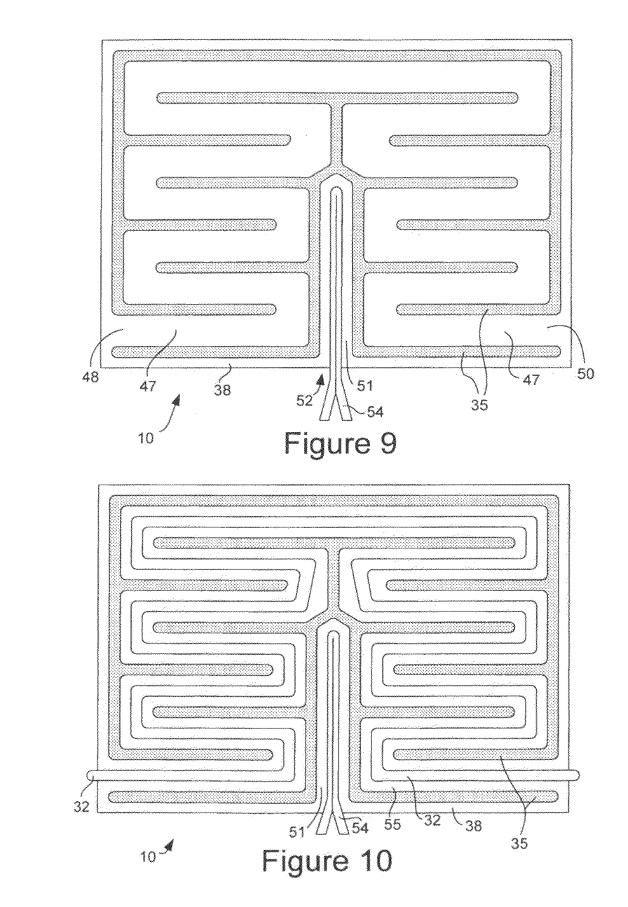

Another alternative embodiment of a device 10 the present invention is shown in a cutaway cross-sectional plan view in FIG. 9. Consolidated wall structures 35 formed of consolidated frit are supported on a substrate 38. The wall structures 35 define a first passage 47 within the device accessible through a fluidic input port 48 and a fluidic output port 50. The wall structures 35 also define a second passage 51 within said body accessible through an access port 52, with the second passage 51 not in fluid communication with the first passage 47. The second passage 51 contains a solid object therein in the form of a metal thermocouple 54. The thermocouple 54 rests in the second passage 51 substantially without compressive stress from the walls or the substrates of the device 10, at least at room temperature.

Another alternative embodiment of a device 10 of the present invention is shown in FIG. 10. The substrate 38 and wall structures 35 are the same as in FIG. 9, but in this embodiment both passages in this particular layer of the device 10 contain respective solid objects therein, in the form of a metal thermocouple 54 and a metal resistive heater 32. The thermocouple 54 rests in the passage 51 substantially without compressive stress from the walls or the substrates of the device 10, at least at room temperature, while the resistive heater 32 rests in the passage 55 substantially without compressive stress from the walls of the substrates of the device 10, at least at room temperature. In this embodiment, fluidic passages in other layers of the device can be provided with a controlled elevated temperature by the combination of the heater element and the thermocouple temperature sensor integrated into the device 10. The stress-free integration of the present invention allows for a long lifetime of reliable use of the device 10.

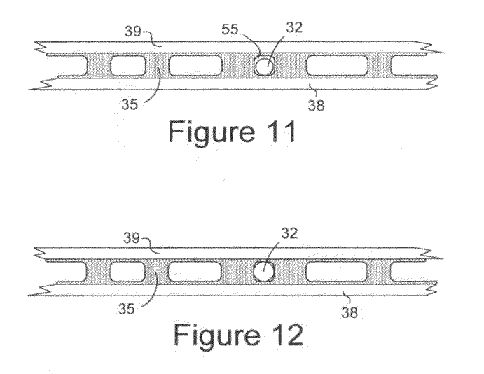

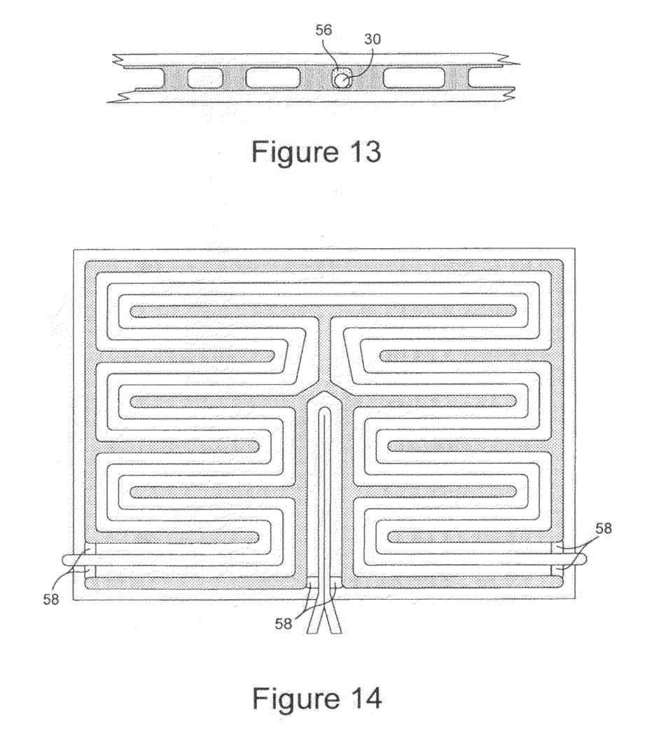

FIGS. 11 and 12 show another alternative or optional feature of the present invention. Where a resistive heating element 32 is integrated into a microfluidic device according to the present invention, the element 32 is stress-free at room temperature, that is, the element is resting in the passage 55 substantially without compressive stress from the walls (the wall structures 35) or the substrates of said device at room temperature. It is generally preferred that this stress-free condition prevail throughout the operating temperature range of the device. However, in order to maximize heat transfer during heating, it is an optional feature of the present invention to size the resistive heater element 32 sufficiently tightly in the passage 55, as shown for example in FIG. 11, such that the heater element 32 expands sufficiently to contact two or more of the inside surfaces of the passage 55 upon heating to a desired heater element operating temperature, as shown for example in FIG. 12. This allows for a controlled amount of stress, generated by the expanded heater element 32 contacting the inside surfaces of the passage 55, to be traded off against faster thermal response to the heat energy supplied by the heater element 32.

As another optional alternative for improved heat transfer to or from an incorporated object 30, a thermally conductive material 56 may be provided within the passage which contains the incorporated object. The thermally conductive material 56 may be a liquid or liquid-like material that can be flowed or pumped into the volume of space surrounding the incorporated object 30. If the thermally conductive material is a liquid or a flowable material and has a high coefficient of thermal expansion, pressure relieving seals 58 such as high temperature elastomeric seals may be provided at the access ports in through which the incorporated object is accessed, so as to retain the material 58 and allow for pressure relief. One embodiment of such seals 58 is shown, for example, in FIG. 14.

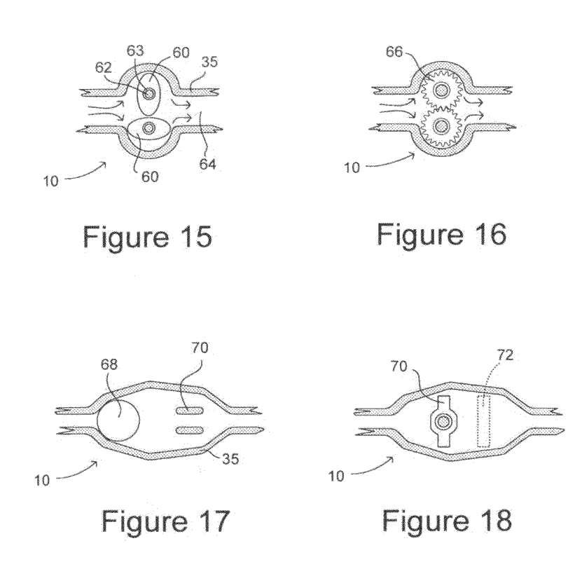

As another alternative within the scope of the present invention, solid objects may also be incorporated in a stress-free manner directly into channels or paths which are structured or arranged for the passage of fluids. FIG. 15 is a partial plan view of a device 10 according to the present invention in which wall structures 35 define a first passage 64 structured and arranged for the passage of fluids. In this embodiment, the solid objects, which may be metal or ceramic or other suitable material, are in the form of oval gears 60 that may act as a flow meter or as a pump or both. For ease of depiction, teeth are not shown in FIG. 15.

The oval gears 60 include a hole 63 which fits with some clearance over posts 62 that serve to locate and retain the gears 60. For pumping applications, the gears may be externally magnetically driven or by other suitable means. For flow metering, rotations may be magnetically, optically, or otherwise measured and counter. As an additional alternative, circular gears 66 may be employed, as shown in FIG. 16. Either set of gears may also function to increase mixing to some degree.

FIG. 17 is a plan view of ball valve, which is another embodiment of a solid structure incorporated within a microfluidic device in a stress-free manner. In the device 10 of FIG. 17, ball 68 plugs the path or passage if fluid attempts to flow leftwards in the figure. Rightwards, baffles 70, formed in this case of the same wall material as wall structures 35, prevent the ball 68 from stopping the flow.

In yet another embodiment of a solid structure incorporated within a glass microfluidic device in a stress-free manner, a magnetic stirrer 70 is placed over a post 62. Alternatively, a free magnetic stirrer 72 may simply be left fee in then channel or passage. In either case, rotation of the stirrer by an external magnetic field or other suitable means contributes to the mixing of the fluids within the device.

What is claimed is:

1. A microfluidic device comprising:
a glass, glass-ceramic, or ceramic structure, said structure including one or more passages defined therein;
at least one first passage accessible through at least one first port;
wherein said first passage contains at least one solid object disposed therein, said solid object including a material having a coefficient of thermal expansion differeing from the glass, glass-ceramic, or ceramic of said structure, said solid object resting in said first passage substantially without compressive stress from an inside surface of said passage at room temperature.

2. The device according to claim 1 wherein the solid object comprises metal.

3. The device according to either claim 1 or claim 2 wherein the solid object is an extended tortuously shaped solid object and said first passage is a correspondingly shaped passage.

4. The device accordingly to any of claims 1-3 wherein said solid object comprises a resistance heater.

5. The device according to any of claims 1-4 wherein said solid object comprises a thermocouple.

6. The device according to any of claims 1-5 wherein said first passage within which said solid object is disposed includes a thermally conductive material disposed therein.

7. The device according to claim 6 wherein the thermally conductive material is a thermally conductive fluid, gel or paste.

8. The device according to either of claims 6 and 7 wherein said thermally conductive material is sealed in said first passage by pressure-relieving seals.

9. The device according to any of claims 1-8 wherein said solid object rests in said first passage substantially without compressive stress from the inside surface of said passage throughout an operating temperature range of said device including room temperature.

10. The device according to any of claims 1-9 wherein said solid object rests in said first passage substantially without compressive stress from the inside surface of said passage at room temperature but contacts the inside surface of said passage upon heating of said object.

11. The device according to any of claims 1-10 further comprising a second passage accessible through a fluidic entrance port and a fluidic exit port.

12. The device according to claim 11 wherein the first and second passages are not in fluid communication one with another within the device.

13. The device according to either claim 1 or claim 2 wherein the first port is a first fluid port such that the solid object is positioned so as to be in contact with such fluid as may be flowed into said first port during use of the microfluidic device.

14. The device according to claim 13 wherein the solid object comprises two mating gears adapted for pumping or flow measurement or the like.

15. The device according to any of claims 1-14 wherein said first passage is comprised of consolidated frit positioned and arranged between two or more substrates.

16. A method of making a microfluidic device comprising glass, glass-ceramic, or ceramic and having a solid structure incorporated therein having a thermal expansion coefficient differing from said glass, glass-ceramic, or ceramic, the method comprising:
providing a solid structure for incorporation into a microfluidic device;
forming, in a glass, glass-ceramic, or ceramic material, an open-ceiling passage;
positioning said solid structure in said passage;
enclosing said solid structure within said passage so as to form an enclosed passage within said device containing said solid structure.

17. The method according to claim 16 wherein the step of providing a solid structure comprises providing a solid structure comprising metal.

18. The method according to either claim 16 or claim 17 wherein providing said solid structure further comprises providing an extended tortuous solid structure.

19. The method according to claim 18 wherein the step of forming an open-ceiling passage comprises forming an extended tortuous passage having a shape corresponding to said extended tortuous structure.

20. The method according to either claim 16 or claim 17 wherein the step of positioning said solid structure in said passage comprises positioning said solid structure in a passage structured and arranged to receive fluids during us of the device.
